(19) United States
(12) Patent Application Publication
(10) Pub. No.: US 2025/0311391 A1
(43) Pub. Date: Oct. 2, 2025

(54) 4H-SiC LATERAL BIDIRECTIONAL JBS DIODE INTEGRATED MOSFET

(71) Applicant: The Research Foundation for the State University of New York, Albany, NY (US)

(72) Inventors: Seung Yup Jang, Cohoes, NY (US); Woongje Sung, Albany, NY (US)

(21) Appl. No.: 19/095,864

(22) Filed: Mar. 31, 2025

Related U.S. Application Data
(60) Provisional application No. 63/571,725, filed on Mar. 29, 2024.

(51) Int. Cl. H10D 84/00; H10D 8/50; H10D 8/60; H10D 30/65; H10D 62/10; H10D 62/40; H10D 62/83; H10D 62/832; H10D 62/834

(52) U.S. Cl. CPC H10D 84/156; H10D 8/50; H10D 8/60; H10D 30/65; H10D 62/106; H10D 62/127; H10D 62/40; H10D 62/83; H10D 62/8325; H10D 62/834; H10D 84/153

(57) ABSTRACT

A 4H-SiC lateral bi-directional JBS diode integrated MOSFET (L-BID-JBSFET). The unit cell of the L-BiD-JBSFET is constructed by connecting two SiC lateral JBSFET unit cells back-to-back with a common-drain configuration. Alternate embodiments include SiC lateral MOSFET and SiC lateral JBSFET devices. A Schottky region can be integrated within a lateral MOSFET cell structure to form the JBSFET.

### CROSS-REFERENCE TO RELATED APPLICATION

This invention claims the benefit of U.S. Provisional Patent Application No. 63/571,725, filed on Mar. 29, 2024, the entirety of which is hereby incorporated herein by this reference.

### BACKGROUND OF THE INVENTION

### 1. Field of the Invention

The present invention generally relates to semiconductors and methods of their fabrication. More particularly, the present invention relates to a high voltage 4H-SiC lateral bi-directional JBS diode integrated MOSFET and JBSFET.

### 2. Description of the Related Art

Silicon carbide (4H-SiC) is one of the primary wide-band-gap semiconductors for high power and harsh environment applications because of its physical properties, such as a high critical electric field and high thermal conductivity. Discrete 4H-SiC diodes and metal-oxide-semiconductor field effect transistors (MOSFETs) are being widely adopted for high voltage power conversion in hybrid/electric vehicles, solar and wind energy generation, and various high temperature applications, enabling significant advances for next-generation energy efficient power systems. Moreover, 4H-SiC can be further developed and refined with integrated circuit (IC) technology.

One example of 4H-SiC is bidirectional power switches is capable of conducting and blocking in both forward and reverse directions and has emerged as essential components for various applications such as current source inverters (CSis) and matrix converters. Previous circuits incorporating bi-directional switches were built utilizing multiple MOSFET and diode components, leading to increased switching losses. Integrating these components into a single device would reduce the overall number of components, thereby improving both switching performance and device efficiency.

In recent years, there have been several demonstrations of 4H-SiC bidirectional switches as single monolithically integrated devices have been observed. However, to further improve 4H-SiC switches, it is desirable to incorporate a junction barrier Schottky (JBS) diode within the MOSFET structure to bypass the PN body diode. This integration is crucial because a bi-directional MOSFET essentially connects two separate MOSFETs back-to-back, requiring an operating mode that allows current to flow through the body diode of the reversed-connected MOSFET. It is thus to such an improvement that the present invention is primarily directed.

### BRIEF SUMMARY OF THE INVENTION

Briefly described, the present invention includes a cell-to-cell integrated 600 V 4H-SiC Lateral Bi-directional JBS diode integrated MOSFET (L-BID-JBSFET) with the integration of Schottky diodes in each JBSFET unit cell. In one embodiment, a junction barrier Schottky (JBS) diode is integrated within the MOSFET structure to bypass a PN body diode. This integration is important because a bi-directional MOSFET essentially connects two separate MOSFETs back-to-back, requiring an operating mode that allows current to flow through the body diode of the reversed-connected MOSFET. Thus, the present 4H-SiC lateral bi-directional JBS Diode integrated MOSFET (L-BiD-JBSFET) can safely and efficiently flow 600V.

In one embodiment, the invention provides a 4H-SiC JBSFET device made on a 4H SIC N+ substrate with a N-epitaxial layer formed on the substrate. There are at least two back-to-back connected JBSFET unit cells formed in the N-epitaxial layer, with each JBSFET unit cell formed without any drain terminal. There is a common-drain structure formed in the N-epitaxial layer and shared between each JBSFET unit cell and there is a Schottky region integrated within each JBSFET unit cell. Each JBSFET unit cell can include a P+ source and each Schottky region is formable by interrupting the P+ source.

Further, each Schottky region can be protectable by the P+ source being placed in a reverse bias, and each JBSFET unit cell can be bi-directionally conductive. The two JBSFET cells can form a 4-terminal L-BiD-JBSFET device. The device can be embodied with the N-epitaxial layer formed from an N-type polysilicon and the P+ source is formed from Al and N implants. Further, the common-drain structure is formed from an interlayer dielectric.

In an embodiment, the invention can include a 4H-SiC JBSFET cell itself, formed on a 4H SIC N+ substrate, with an N-epitaxial layer on the substrate. The JBSFET cell is formed in the N-epitaxial layer with the JBSFET unit cell formed without any drain terminal. There is a drain structure formed in the N-epitaxial later and in conductive contact with the JBSFET cell, with and a Schottky region integrated within the JBSFET cell.

In one embodiment, the invention provides a lateral, bidirectional MOSFET device on a 4H SIC N+ substrate with a N-epitaxial layer on the substrate. There is a gate formed on the N-epitaxial layer and a source also formed on the N-epitaxial layer adjacent the gate. There is a drain formed on the N-epitaxial layer, a P-well formed in the N-epitaxial layer beneath the gate and the source an interlayer dielectric formed in the N-epitaxial later and shared between the source and the drain. There is a P+ source formed in the N-epitaxial layer on the P-well and at least partially beneath the interlayer dielectric, and a Schottky region is formed by the P+ source and P-well.

The present invention provides an advantage in the fabrication of bi-directional MOSFETs. The present invention is industrially applicable in the fabrication of semiconductor devices, including MOSFETs and JBSFETs. Other features and advantages of the present invention will be apparent to one of skill in the art after review of the present application.

### BRIEF DESCRIPTION OF THE DRAWINGS

FIG. 1 is a schematic cross-sectional view of the SiC lateral bi-directional JBSFET (L-BID-JBSFET) with common-drain configuration.

FIG. 2 is a circuit diagram for one embodiment of the 4-terminal L-BiD-JBSFET device.

FIG. 3A is a schematic cross-sectional view of one embodiment of a lateral PIN (L-PiN) diode.

FIG. 3B is an optical microscopic image of the L-PiN diode of FIG. 3A.

FIG. 3C is a schematic cross-sectional view of one embodiment of a lateral JBS (L-JBS) diode.

FIG. 3D is an optical microscopic image of the L-JBS diode of FIG. 3C.

FIG. 4 is a graph of a measured and simulated forward characteristics of the fabricated L-PiN diode and L-JBS diode.

FIG. 5A is a schematic cross-sectional view of one embodiment of a lateral MOSFET (L-MOSFET).

FIG. 5B is an optical microscopic image of the L-MOSFET of FIG. 5A.

FIG. 5C is a schematic cross-sectional view of one embodiment of a lateral JBSFET (L-JBSFET).

FIG. 5D is an optical microscopic image of the L-JBSFET of FIG. 5C.

FIG. 6A is a graph of measured output characteristics of a fabricated L-MOSFET.

FIG. 6B is a graph of measured output characteristics of a fabricated L-JBSFET.

FIG. 7A is a graph of a comparison between the output characteristics of the L-MOSFET and L-JBSFET when VGS=25 V.

FIG. 7B is a graph of a comparison between the output characteristics of the L-MOSFET and L-JBSFET when VGS=0V.

FIG. 8A is a schematic cross-sectional view of one embodiment of a lateral Bi-directional MOSFET (L-BID-MOSFET).

FIG. 8B is an optical microscopic image of the L-BiD-MOSFET of FIG. 8A.

FIG. 8C is a schematic cross-sectional view of one embodiment of a lateral bi-directional JBSFET (L-BID-JBSFET).

FIG. 8D is an optical microscopic image of the L-BiD-JBSFET of FIG. 8C.

FIG. 9A is a graph of measured output characteristics of the L-BiD-JBSFET with 25 V gate bias.

FIG. 9B is a graph of measured output characteristics of the L-BiD-JBSFET with 0 V gate bias.

FIG. 10A is a graph of measured and simulated 1st quadrant output curves for the L-BiD-JBSFET with both gates having 25 V.

FIG. 10B is a graph of measured and simulated 1st quadrant output curves for the L-BID-MOSFET with both gates having 25 V.

FIG. 11 is a graph of measured forward and reverse blocking characteristics of the L-BID-JBSFETs for the high JFET doping and low JFET doping cases.

### DETAILED DESCRIPTION OF THE INVENTION

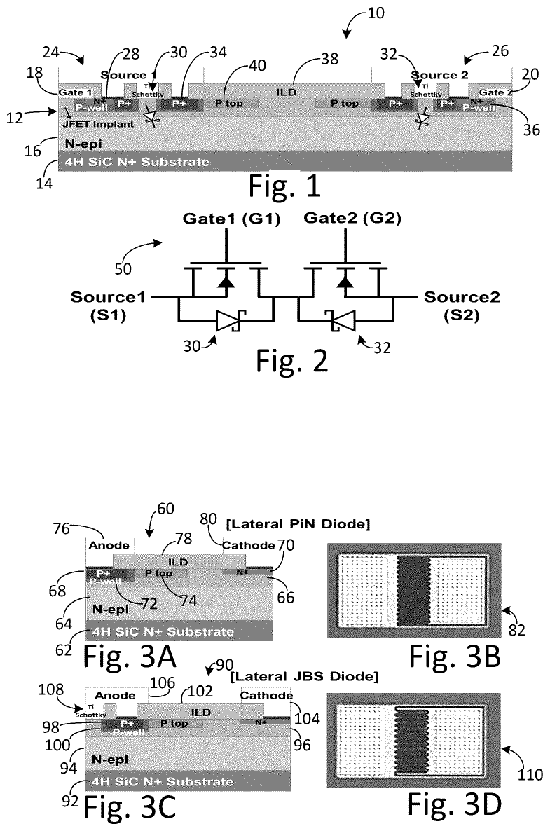

With reference to the figures in which like numerals represent like elements throughout the several views, FIG. 1 is a schematic cross-sectional view of the SiC lateral bi-directional JBSFET 10 (L-BID-JBSFET) with common-drain 12 configuration. It employs a common-drain structure 12 where two back-to-back connected JBSFET unit cells (unit cell 24 and unit cell 26) share the N-epitaxial layer 14 in the middle without any drain terminal. There is a first gate 18 and second gate 20 in each JBSFET unit cell 24,26. The 4H-SiC JBSFET device 10 is made on a 4H SIC N+ substrate 14 with a N-epitaxial layer 16 formed on the substrate 14. There are at least two back-to-back connected JBSFET unit cells 24,26 formed in the N-epitaxial layer 16, with each JBSFET unit cell 24,26 formed without any drain terminal. There is a common-drain structure 12 formed in the N-epitaxial layer 16 and shared between each JBSFET unit cell 24,26 and there is a Schottky region 30,32 integrated within each JBSFET unit cell 24,26. Each JBSFET unit cell 24,26 can include a P+ source 34 and each Schottky region 30,32 is formable by interrupting the P+ source 34.

Further, each Schottky region 30,32 can be protectable by the P+ source 34 being placed in a reverse bias, and each JBSFET unit cell 24,26 can be bi-directionally conductive. The two JBSFET unit cells 24,26 can form a 4-terminal L-BiD-JBSFET device. The device 10 can be embodied with the N-epitaxial layer 16 formed from an N-type polysilicon and the P+ source 34 can be formed from Al and N implants. Further, the common-drain structure 12 can include an interlayer dielectric 38.

FIG. 2 is a circuit diagram 50 for one embodiment of the 4-terminal L-BiD-JBSFET device. The sources and the gates of the JBSFETs designated as S1, S2 and G1, G2, respectively.

When a Schottky region 30,32 is integrated within the lateral MOSFET cell structure to form a JBSFET, it is allocated by interrupting the P-well 36 and/or P+ source 34 in the MOSFET cell. Therefore, the Schottky region 30,32 can be protected by the P-well 36 and/or P+ source 36 in reverse bias situation. However, due to the inclusion of the Schottky region 30,32 and P+ well 36 (P+ source 34), the cell pitch of the lateral JBSFET becomes larger than that of the standalone lateral MOSFET. Nevertheless, a sufficient Schottky region 30,32 achieves a good 3rd quadrant conduction of single JBSFET and eventually a good bi-directional conductivity.

There is an Al implanted P top 40 is utilized to alleviate the surface electric field and enhance the breakdown voltage. The 4-terminal L-BiD-JBSFET device symbol is shown in FIG. 2, where the Schottky diode 30,32 is integrated instead of the PiN body diode.

One method of fabricating a L-BiD-JBSFET device is 10 μm thick drift layer with N-type doping concentration of 8×10¹⁵ cm-3 on an N+ 4H-SiC substrate 14. Aluminum and Nitrogen ion implants can be used to form the P-well 36/P+ source 34/P top 40, and JFET/N+ source 28, respectively. At the conclusion of all the implantation steps, a 1650° C., 10-min activation anneal with a carbon cap can be conducted. A 50 nm thick gate oxide can be formed, followed by a post-oxidation annealing (POA) in NO ambient. An N-type polysilicon can deposited and patterned for the formation of the gate 18,20. After, an interlayer dielectric (ILD) 38 is deposited, patterned and etched to make ohmic contact regions. Nickel (Ni) was deposited and rapid thermal annealing (RTA) was performed to form Ni silicide. After removing the unsilicided Ni metal, the RTA process can be performed at 1000° C. for 2 minutes. After the formation of ohmic contacts, the ILD 38 on the Schottky 30,32 area was etched while etching the ILD 38 on Polysilicon, making a contact to the top metal (Ti/TiN/AlCu). Thus, Ti forms Schottky on SiC and there is no additional process required to make the JBSFET along with pure MOSFETs. After the top metal deposition, the source and gate pads are patterned and etched. For the passivation, Silicon Nitride (SiN) is deposited, patterned, and etched.

FIG. 3A is a schematic cross-sectional view of one embodiment of a lateral PiN (L-PiN) diode 60. There is a 4H SiC N+ substrate 62 upon which is formed an N-eptaxial layer 64. There is an anode 76 and cathode 80 at the top of the stack. There is a common drain layer 66 upon which a P top 74 is used to reduce the field on the surface in both structures. A P+ source 68 is formed over a P-well 72 beneath the anode 76 and an N+ ion implantation 70 is formed under the cathode 80 and a portion of the interlayer dielectric 78. FIG. 3B is an optical microscopic image 82 of the L-PiN diode of FIG. 3A.

FIG. 3C is a schematic cross-sectional view of one embodiment of a lateral JBS (L-JBS) diode 90. There is a 4H SiC N+ substrate 92 upon which is formed an N-eptaxial layer 94. There is an anode 106 and cathode 104 at the top of the stack. There is a common drain layer 96 upon which a P top is used to reduce the field on the surface in both structures. A P+ source 98 is formed within a P-well 100 beneath the anode 106 and an N+ ion implantation is formed under the cathode 104 and a portion of the interlayer dielectric 102. There is also a Schottky region 108 formed between the anode 106 and common drain layer 96. FIG. 3D is an optical microscopic image 110 of the L-PiN diode of FIG. 3C.

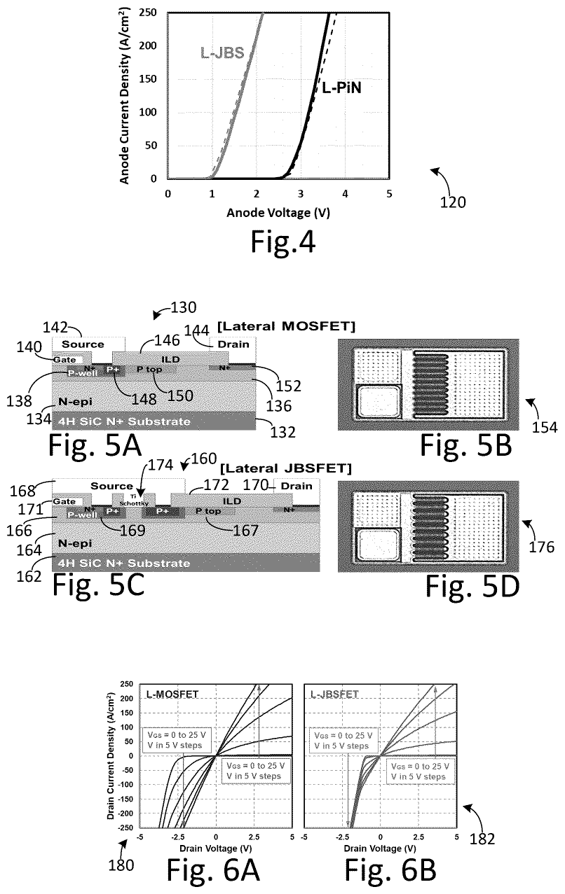

FIG. 4 is a graph 120 of the measured (solid line) and simulated (dashed line) forward characteristics of the fabricated L-PiN diode and L-JBSdiode. FIG. 4 displays the forward characteristics of both the L-JBS and L-PiN diodes. The knee voltage of the L-JBS diode is measured to be approximately 1 V. Despite the L-JBS diode having a 12% larger cell pitch compared to the L-PiN diode, the specific on-resistance (˜4 mΩ·cm2) is comparable to that of the PiN diode, indicating the high quality of the titanium Schottky surface.

FIG. 5A is a schematic cross-sectional view of one embodiment of a lateral MOSFET (L-MOSFET) 130. There is a 4H SiC N+ substrate 132 upon which is formed an N-eptaxial layer 134. There is a source 142 and drain 144 at the top of the stack, with a gate 140 formed over the common drain layer 136, upon which a P top 150 is used to reduce the field on the surface in both structures. A P+ source 148 is formed over a P-well 138 beneath the source 142 and an N+ ion implantation 152 is formed under the drain 144 and a portion of the interlayer dielectric 146. FIG. 5B is an optical microscopic image 154 of the L-MOSFET of FIG. 5A.

FIG. 5C is a schematic cross-sectional view of one embodiment of a lateral JBSFET (L-JBSFET) 160. There is a 4H SiC N+ substrate 162 upon which is formed an N-eptaxial layer 164. There is a source 168 and drain 170 at the top of the stack, with a gate 171 formed over the common drain layer 166, upon which a P top 167 is used to reduce the field on the surface in both structures. An interlayer dielectric 146 172 is between the source 168 and drain 170. The cell pitch of the L-JBSFET 160 can be increased by 26.5% by introducing Schottky region 174 in the middle of P-body region 169 (P-well and P+ source). FIG. 5D is an optical microscopic image 176 of the L-JBSFET of FIG. 5C.

FIG. 6A is a graph 180 of measured output characteristics of a fabricated L-MOSFET. FIG. 6B is a graph 182 of measured output characteristics of a fabricated L-JBSFET. FIGS. 6A-6B show the 1st and 3rd output characteristics of the fabricated L-MOSFET and L-JBSFET, with gate voltages ranging from 0 V to 25 V in 5 V increments. As anticipated, the 1st quadrant specific on-resistance of the L-JBSFET is 27% higher than that of the L-MOSFET due to increased cell pitch, as calculated in Table I below.

### Measurement Results of the L-MOSFET and L-JBSFET

TABLE I

| | L-MOSFET | L-JBSFET |
|---|---|---|
| Specific On-Resistance | 9.9 mΩ · cm² | 12.6 mΩ · cm² |
| (V_{GS} = 25 V, V_{DS} = 1 V) | | |
| Voltage Drop | −3.2 V | −1.4 V |
| (V_{GS} = 0 V, I_{DS} = −100 A/cm²) | | |

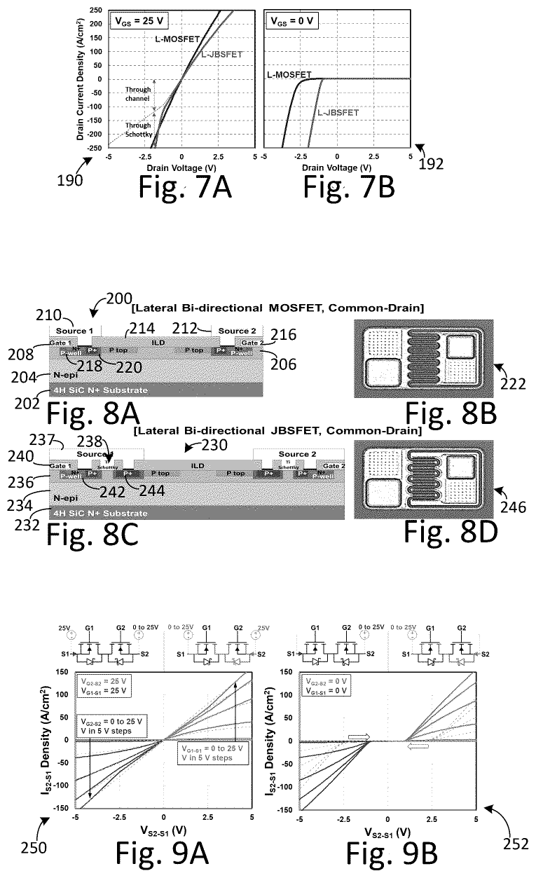

FIG. 7A is a graph 190 of a comparison between the output characteristics of the L-MOSFET and L-JBSFET when VGS=25 V. FIG. 7B is a graph 192 of a comparison between the output characteristics of the L-MOSFET and L-JBSFET when VGS=0V. The 3rd quadrant characteristics of L-JBSFET surpass those of L-MOSFET due to the involvement of Schottky conduction. Firstly, when the gate is OFF, the voltage drop at −100 A/cm2 of L-JBSFET is only 43% of that of the L-MOSFET, as shown in the Table I. Moreover, even with the gate ON, the 3rd quadrant conduction of L-JBSFET exceeds that of L-MOSFET when the drain bias is lower than-2 V (FIG. 7A). This occurs because the 3rd quadrant conduction involves not only the channel but also the forward conduction of the Schottky region, as shown by the simulation analysis in FIG. 7A. This superior 3rd quadrant conductivity favors bi-directional conduction, because conduction in a bi-directional device is the series connection of the forward conduction of one device with the reverse conduction of another device.

FIG. 8A is a schematic cross-sectional view of one embodiment of a lateral Bi-directional MOSFET (L-BID-MOSFET) 200. In this embodiment, a lateral, bidirectional MOSFET device 200 is formed on a 4H SIC N+ substrate 202 with a N-epitaxial layer 204 on the substrate 202. There is a gate 208 formed on the N-epitaxial layer 204 and a source 210 also formed on the N-epitaxial layer 204 adjacent the gate 208, and a source 212 adjacent gate 216. There is a drain layer 206 formed on the N-epitaxial layer 204, a P-well 218 formed in the N-epitaxial layer 204 beneath the gate 208 and the source 210 an interlayer dielectric 214 formed in the N-epitaxial layer 214 and shared between the source 210 and the drain layer 206. There is a P+ source 220 formed in the N-epitaxial layer 204 on the P-well 218 and at least partially beneath the interlayer dielectric 214, and a Schottky region can be formed by the P+ source 220 and P-well 218. (FIG. 8C; Schottky region 238). FIG. 8B is an optical microscopic image 222 of the L-BiD-MOSFET of FIG. 8A.

FIG. 8C is a schematic cross-sectional view of one embodiment of a lateral bi-directional JBSFET (L-BID-JBSFET) 230. Similar to the L-JBSFET 160 (FIG. 5C), the L-BID-JBSFET exhibits an increased cell pitch compared to the L-BiD-MOSFET, with a 29% increase. In this embodiment, a lateral, bidirectional JBSFET device 230 is formed on a 4H SIC N+ substrate 232 with a N-epitaxial layer 234 on the substrate 232. There is a gate 240 formed on the N-epitaxial layer 234 and a source 237 also formed on the N-epitaxial layer 234 adjacent the gate 240. There is a common drain layer 236 formed on the N-epitaxial layer 234, there are two P-wells 242,244 formed in the N-epitaxial layer 204 adjacent the gate 240 and the source 237. There is a Schottky region 238 formed between the P-wells 242,244 and the common drain layer 236. FIG. 8D is an optical microscopic image 246 of the L-BID-JBSFET 230 of FIG. 8C.

FIG. 9A is a graph 250 of measured output characteristics of the L-BiD-JBSFET 230 with 25 V gate bias. FIG. 9B is a graph 252 of measured output characteristics of the L-BiD-JBSFET 230 with 0 V gate bias. The forward and reverse output characteristics of the L-BiD-JBSFET are presented in FIGS. 9A-9B, alongside the output characteristics of the L-BiD-MOSFET 200 (dotted lines) for reference. Notably, the symmetrical bi-directional output characteristics of the L-BiD-JBSFET 230 are confirmed. The internal current flow paths are shown in the schematics adjacent to the graph.

FIG. 9A shows the device controlled by applying a gate voltage to G1-S1 while maintaining the gate voltage across G2-S2 constant at 25 V in the 1st quadrant. In the 3rd quadrant, the device was controlled by applying a gate voltage to G2-S2 while maintaining the bias across G1-S1 constant at 25V. Having the opposite gate turned-on allows current to flow through both channels.

FIG. 9B depicts the results of applying a gate voltage to G2-S2 with G1-S1 shorted in the 1st quadrant, and applying a gate voltage to G2-S2 with G1-S1 shorted in the 3rd quadrant. With the opposite gate is closed, current flows through the body diode, generating a specific knee voltage in both directions. The knee voltage of the L-BID-JBSFET 230 (˜1 V) is approximately 1.5 V lower than that of the L-BiD-MOSFET 200 (˜2.5 V), which is attributed to the internal Schottky region 238 being operated. This reduction to less than half of the L-BiD-MOSFET's knee voltage will result in significantly reduced conduction loss.

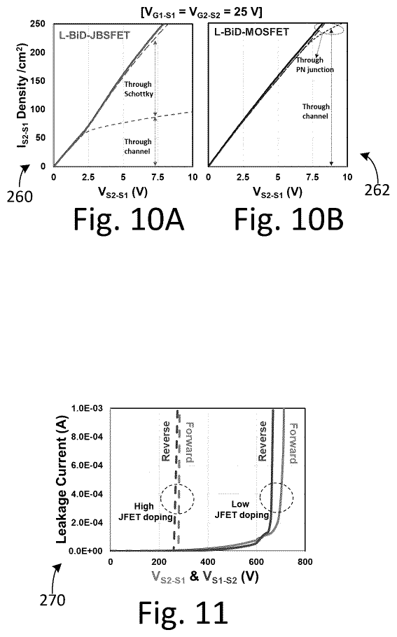

Further, in FIG. 9A, the output characteristics of the L-BID-JBSFET 230, with both gates ON, are comparable in current density to those of L-BID-MOSFET 200, despite differences in single device specific on-resistance. To further illustrate this, the measured and simulated 1st quadrant output characteristics of both the L-BiD-JBSFET and L-BID-MOSFET 200 with both gates ON are analyzed, as seen in FIGS. 10A-10B.

FIG. 10A is a graph 260 of measured and simulated 1st quadrant output curves for the L-BID-JBSFET 230 with both gates having 25 V. FIG. 10B is a graph 262 of measured and simulated 1st quadrant output curves for the L-BID-MOSFET 200 with both gates having 25 V. As indicated by the simulated curve, in the case of the L-BiD-JBSFET 230, a notable amount of current flows through the Schottky region 238 even when both channels are open, provided that VS2-S1 exceeds 2 V. Beyond 5 V of VS2-S1, the Schottky current becomes predominant. This feature is unique to the L-BiD-JBSFET 230 and is attributed to the reverse conduction characteristics of the JBSFET. In contrast, the L-BID-MOSFET 200 only permits current flow though the channel up to approximately 7 V, with bipolar current initiation beyond this voltage. Despite the wider cell pitch of the L-BID-JBSFET 230 compared to the L-BiD-MOSFET 200, the presence of Schottky current explains the comparable current density in their overall conduction characteristics.

FIG. 11 is a graph 270 of measured forward and reverse blocking characteristics of the L-BID-JBSFETs 230 for the high JFET doping and low JFET doping cases. The breakdown voltage (BV) of L-BiD-JBSFET devices was found to be highly dependent on the JFET doping concentrations. Through careful optimization of the doping concentration, BV values over 600V can achieved for both directions of operation, as shown in FIG. 11.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of one or more aspects of the invention and the practical application, and to enable others of ordinary skill in the art to understand one or more aspects of the invention for various embodiments with various modifications as are suited to the particular use contemplated.

What is claimed is:

1. A 4H-SiC JBSFET device, comprising:
a 4H SIC N+ substrate;
an N-epitaxial layer on the substrate;
at least two back-to-back connected JBSFET unit cells formed in the N-epitaxial layer, each JBSFET unit cell formed without any drain terminal;
a common-drain structure formed in the N-epitaxial later and shared between each JBSFET unit cell; and
a Schottky region integrated within each JBSFET unit cell.

2. The device of claim 1, wherein each JBSFET unit cell includes a P+ source and each Schottky region is formable by interrupting the P+ source.

3. The device of claim 2, wherein each Schottky region is protectable by the P+ source being placed in a reverse bias.

4. The device of claim 1, wherein each JBSFET unit cell is bi-directionally conductive.

5. The device of claim 1, wherein the at least two JBSFET cells forming a 4-terminal L-BiD-JBSFET device.

6. The device of claim 5, wherein the L-BID-JBSFET device flows a current of about 600V.

7. The device of claim 1, wherein the N-epitaxial layer is formed from an N-type polysilicon.

8. The device of claim 2, wherein the P+ source is formed from Al and N implants.

9. The device of claim 1, wherein common-drain structure is formed from an interlayer dielectric.

10. A 4H-SiC JBSFET cell, comprising:
a 4H SIC N+ substrate;
a N-epitaxial layer on the substrate;
a JBSFET cell formed in the N-epitaxial layer, the JBSFET cell formed without a drain terminal;
a drain structure formed in the N-epitaxial later and in conductive contact with the JBSFET cell; and
a Schottky region integrated within the JBSFET cell.

11. The JBSFET cell of claim 10, wherein the JBSFET cell includes a P+ source and the Schottky region is formable by interrupting the P+ source.

12. The JBSFET cell of claim 11, wherein the Schottky region is protectable by the P+ source being placed in a reverse bias.

13. The JBSFET cell of claim 10, wherein JBSFET cell is bi-directionally conductive.

14. The JBSFET cell of claim 10, further having 2 terminals.

15. The JBSFET cell of claim 14, wherein the JBSFET cell is configured to flow a current over 600V.

16. The JBSFET cell of claim 10, wherein the N-epitaxial layer is formed from an N-type polysilicon.

17. The JBSFET cell of claim 11, wherein the P+ source is formed from Al and N implants.

18. The JBSFET cell of claim 10, wherein drain structure is formed from an interlayer dielectric.

19. A lateral, bidirectional MOSFET device, comprising:
a 4H SIC N+ substrate;
a N-epitaxial layer on the substrate;
a gate formed on the N-epitaxial layer;
a source formed on the N-epitaxial layer adjacent the gate;
a drain formed on the N-epitaxial layer;
a P-well formed in the N-epitaxial layer beneath the gate and the source;
an interlayer dielectric formed in the N-epitaxial later and shared between the source and the drain;
a P+ source formed in the N-epitaxial layer on the P-well and at least partially beneath the interlayer dielectric; and
a Schottky region formed by the P+ source and P-well.

20. The device of claim 19, wherein the Schottky region is formable by interrupting the P+ source.
